(19) United States
(12) Patent Application Publication
(10) Pub. No.: US 2024/0312955 A1
(43) Pub. Date: Sep. 19, 2024

(54) Bonding Structure

(71) Applicant: Teknologian tutkimuskeskus VTT Oy, Espoo (FI)

(72) Inventors: Jae-Wung Lee, Espoo (FI); Mikko Harjanne, Espoo (FI); Tomi Hassinen, Espoo (FI)

(21) Appl. No.: 18/576,759

(22) PCT Filed: Jun. 30, 2022
(86) PCT No.: PCT/FI2022/050482

§ 371 Date: Jan. 5, 2024

(30) Foreign Application Priority Data
Jul. 6, 2021 (FI) 20215792

(51) Int. Cl. H01L 23/00; H01L 25/16; H01S 5/0236

(52) U.S. Cl. CPC H01L 24/83; H01L 25/167; H01S 5/0236; H01L 2224/83139; H01L 2224/83805; H01L 2224/83825

(57) ABSTRACT

According to an example aspect of the present invention, there is provided a bonding structure for forming at least one electrical connection between a photonic substrate and an optoelectronic component. The bonding structure comprises an electroconductive pad between the photonic substrate and the optoelectronic component. The electroconductive pad comprises at least two separated portions. The bonding structure comprises a bond layer between the electroconductive pad and the optoelectronic component, and between the at least two portions of the electroconductive pad.

### FIELD

The present invention relates to bonding structures between a substrate and an electronic component, especially bonding structures between an optoelectronic component and a silicon photonic substrate.

### BACKGROUND

Optoelectronic devices are primarily transducers. Therefore, they can convert one energy form to another. These devices produce light by expending electrical energy. They can also detect light and transform light signals to electrical signals. For example, semiconductor optical amplifiers (SOAs), photodiodes (PDs) and laser diodes (LDs) are optoelectronic devices.

An optoelectronic device can be interconnected to a silicon photonic substrate by for example, soldering or eutectic bonding. However, these methods can be sensitive to errors. For example, non-uniformity of bonding temperature and bonding force can cause non-uniformity of bonding quality. Further, non-uniform melting near eutectic temperature and non-uniform bonding force can cause squeezing of bonding material, which can result in electrical shortage and optical misalignment. Furthermore, a small stopper area and thick bonding materials combined with fragile optoelectronic components can cause crack formation in the optoelectronic components. Thus, there is need for improving the bonding structure between the optoelectronic device and the silicon photonic substrate.

### SUMMARY OF THE INVENTION

The object of at least some embodiments is to provide a high quality bonding structure with squeezing control of molten metal and a large stopper area for preventing an optical device for breakage. Further, the object of at least some embodiments is to provide precise alignment between the optical device and a silicon photonic substrate.

According to a first aspect of the present invention, there is provided a bonding structure for forming at least one electrical connection between a photonic substrate and an optoelectronic component, the bonding structure comprising: an electroconductive pad between the photonic substrate and the optoelectronic component, which electroconductive pad comprises at least two separated portions, and a bond layer between the electroconductive pad and the optoelectronic component, and between the at least two portions of the electroconductive pad.

According to an embodiment, the bond layer comprises a eutectic alloy, a solder alloy or an intermetallic alloy.

According to an embodiment, the electroconductive pad (110) has a predetermined height of 0.2 to 1 μm.

According to an embodiment, the bonding structure comprises an optical connection between the photonic substrate and the optoelectronic component.

According to an embodiment, the bonding structure comprises a passivation layer on the photonic substrate.

According to an embodiment, the optoelectronic component comprises at least one groove and the photonic substrate comprises at least one protrusion configured to the at least one groove for aligning the optoelectronic component with the photonic substrate.

According to an embodiment, the bond layer extends on the at least one protrusion and/or on the at least one groove.

According to an embodiment, the at least one protrusion has a shape of a pillar, which pillar is tapering towards the optoelectronic component, and the at least one groove has substantially the same shape than the at least one protrusion and is widening towards the photonic substrate.

According to an embodiment, the photonic substrate is silicon photonic chip or wafer.

According to an embodiment, the optoelectronic component is a semiconductor optical amplifier, a photodiode or a laser diode.

According to a second aspect of the present invention, there is provided a method for forming at least one electrical connection between a photonic substrate and an optoelectronic component comprising: providing an electroconductive pad on a surface of the photonic substrate, providing a first bonding material layer directly and at least partially on a surface of the electroconductive pad, providing a second bonding material layer on a surface of the optoelectronic component, and bonding the first bonding material layer with the second bonding material layer for forming a bond layer, wherein the electroconductive pad for the at least one individual electrical connection comprises at least two separated portions for receiving extra bonding material of the bond layer between the portions.

According to an embodiment, the method comprises providing a first bonding material layer on the surface of the photonic substrate.

According to an embodiment, the method comprises providing a passivation layer on the photonic substrate.

According to an embodiment, a bonding temperature for bonding the first bonding material layer with the second bonding material layer is lower than a melting temperature of the electroconductive pad.

According to an embodiment, bonding of the first bonding material layer with the second bonding material layer is provided by eutectic bonding; solder bonding or solid-liquid interdiffusion.

According to an embodiment, the method comprises: providing at least one groove in the optoelectronic component, and providing at least one protrusion on the photonic substrate for aligning the optoelectronic component with the photonic substrate.

According to an embodiment, the method comprises providing the first bonding material layer on the at least one protrusion and/or the second bonding material layer on the at least one groove.

According to an embodiment, the photonic substrate is silicon photonic chip or wafer.

According to an embodiment, the optoelectronic component is a semiconductor optical amplifier, a photodiode or a laser diode.

According to a second aspect of the present invention, the bonding structure is used in a telecommunication, a datacommunication, an environmental sensing, an industrial sensing, a medial or a light detection and ranging application.

### BRIEF DESCRIPTION OF THE DRAWINGS

FIG. 1 illustrates a bonding structure in accordance with at least some embodiments of the present invention;

FIG. 2 illustrates a bonding structure having a waveguide in accordance with at least some embodiments of the present invention;

FIG. 3 illustrates a bonding structure comprising at least one protrusion and at least one groove for receiving the at least one protrusion in accordance with at least some embodiments of the present invention;

FIG. 4 illustrates a bonding structure comprising at least one protrusion and at least one groove for receiving the at least one protrusion and a waveguide in accordance with at least some embodiments of the present invention;

FIG. 5 illustrates a photonic substrate and an optoelectronic component before bonding in accordance with at least some embodiments of the present invention;

FIGS. 6A to 6C illustrate a photonic substrate before bonding in accordance with at least some embodiments of the present invention;

FIGS. 7A and 7B illustrate a photonic substrate and an optoelectronic component before bonding in accordance with at least some embodiments of the present invention;

FIGS. 8A to 8F illustrate an electroconductive pad and a first bonding material layer on a surface of the electroconductive pad in accordance with at least some embodiments of the present invention; and

FIG. 9 illustrates a protrusion and a groove in accordance with at least some embodiments of the present invention.

### EMBODIMENTS

In the present context, “photonic substrate” refers to a wafer or a chip comprising photonic functionality. The wafer can be for example, silicon wafer. The chip can comprise a waveguide.

In the present context, “optoelectronic component” comprise for example, a semiconductor optical amplifier (SOA), a photodiode (PD) or a laser diode (LD).

In the present context, “gap” refers to a space between portions of an electroconductive pad.

Generally, bonding an optoelectronic component to photonic substrate is sensitive for errors. The present embodiments provide a high quality bonding structure with squeezing control of molten metal.

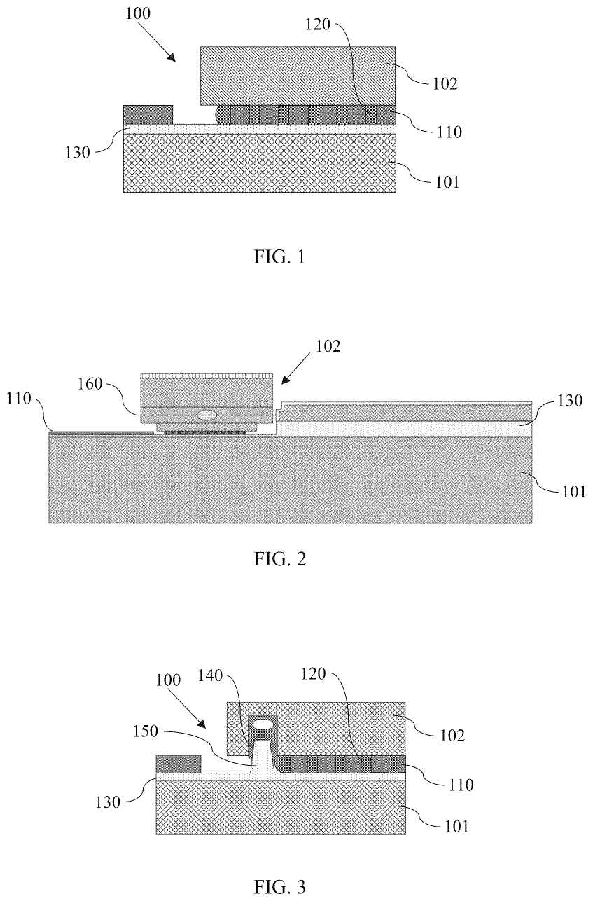

FIG. 1 illustrates a bonding structure 100 for forming at least one electrical connection between a photonic substrate 101 and an optoelectronic component 102 in accordance with at least some embodiments. The bonding structure 100 comprises an electroconductive pad 110 between the photonic substrate 101 and the optoelectronic component 102. The electroconductive pad 110 comprises at least two separated portions. The bonding structure 100 further comprises a bond layer 120 between the electroconductive pad 110 and the optoelectronic component 102, and between the at least two portions of the electroconductive pad 110. The bonding structure provides a squeezing control of molten metal by the portions of the electroconductive pad. The extra molten metal can flow between of the portions the electroconductive pad. So, extra molten metal does not squeeze uncontrollably from between the photonic substrate and the optoelectronic component. The squeezing control prevents the optoelectronic component from breakage. Furthermore, it enables precise alignment between the photonic substrate and the optoelectronic component, and precise thickness control of a structure between the photonic substrate and the optoelectronic component. In addition, the bonding structure is less sensitive to particles on the bonding surface, because the particles easily come out from bonding surfaces during bonding. The bonding structure also provides uniform bonding force distribution.

At least in some embodiments, at least part of the molten metal is contained within the pad. Extra metal flows in the at least one gap between the portions of the pad. So, the dimensions of the final connection structure are better controlled.

The photonic substrate can comprise silicon. Silicon is very reliable photonic substrate material as it suffers very little fatigue and can have long service lifetimes without breaking. In single crystal form, silicon has virtually no hysteresis and hence almost no energy dissipation.

The photonic substrate 101 can be silicon photonic chip or wafer.

The optoelectronic component 102 can be a semiconductor optical amplifier, a photodiode or a laser diode.

According to some embodiments, the bond layer 120 comprises a eutectic alloy, a solder alloy or an intermetallic alloy.

Suitable eutectic, solder and intermetallic alloys comprise, for example, gold-tin (AuSn), aluminium-germanium (AlGe), copper-tin (CuSn).

According to some embodiments, the electroconductive pad 110 has a predetermined height of 0.2 to 1 μm. Thus, the electroconductive pad controls a height of a gap between the photonic substrate and the optoelectronic component.

The electroconductive pad 110 can comprise for example, doped silicon.

Alternatively, the electroconductive pad 100 can comprise metal or metal alloy, such as platinum (Pt), molybdenum (Mo), titanium-tungsten (TiW), aluminum (Al) or tantalum nitride (TaN). These metals enable good and reliable electrical connection.

FIG. 1 illustrates that bonding structure comprises a passivation layer 130 on the photonic substrate 101. Then, the electroconductive pad 110 can be on a surface of the passivation layer 130. The passivation layer prevent short-circuiting.

The passivation layer can comprise silicon dioxide (SiO₂), aluminum oxide (Al₂O₃) or aluminum nitride (AlN), for instance.

FIG. 2 illustrates a bonding structure 100 in accordance with at least some embodiments. The bonding structure 100 has a silicon (Si) waveguide 160 on the photonic substrate. So, the bonding structure 100 comprises an optical connection between the photonic substrate 101 and the optoelectronic component 102. Further, the bonding structure provides precise alignment between the optoelectronic component and the silicon waveguide.

FIG. 3 illustrates a bonding structure 100 comprising at least one protrusion 150 and at least one groove 140 for receiving the at least one protrusion 150 in accordance with at least some embodiments of the present invention. The optoelectronic component 102 comprises at least one groove 140 and the photonic substrate 101 comprises at least one protrusion 150. The at least one protrusion 150 is configured to the at least one groove 140 for aligning the optoelectronic component 102 with the photonic substrate 101. The protrusion with the groove provides better alignment accuracy between the photonic substrate and the optoelectronic component. Better alignment accuracy minimizes risk for fractures of the photonic substrate and the optoelectronic component.

According to some embodiments, the bond layer 120 extends on the at least one protrusion 150 and/or on the at least one groove 140. This provides better contact between the protrusion and the groove.

The protrusion 150 can have a shape of a pillar, which pillar is tapering towards the optoelectronic component 102. In addition, the groove 140 can have substantially the same shape than the protrusion and widen towards the photonic substrate 101. Then, the protrusion match the groove. Therefore, the protrusion and the groove is easy to set in contact, and the photonic substrate and the optoelectronic component can be aligned to each other with high precision.

The protrusion 150 can have a cross-sectional shape of a square, a circle, an oval or any other suitable shape.

The protrusion 150 can comprise electrical insulator material.

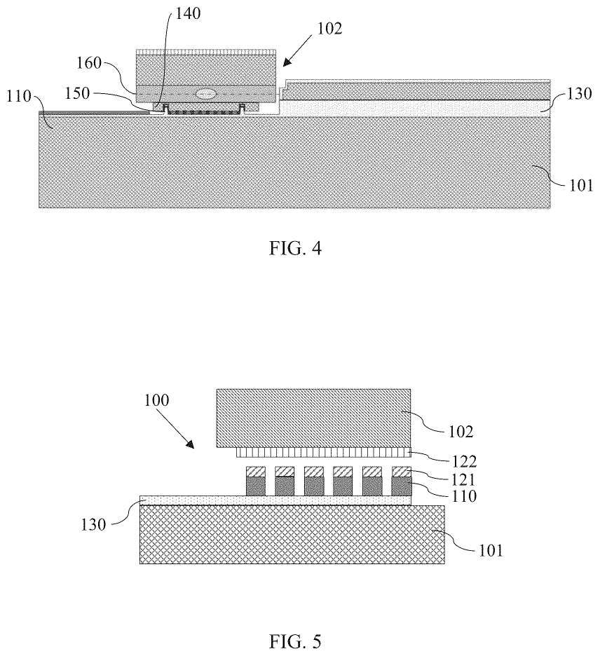

FIG. 4 illustrates a bonding structure 100 comprising at least one protrusion 150 and at least one groove 140 for receiving the at least one protrusion 150 in accordance with at least some embodiments of the present invention. The protrusions 150 are formed on the photonic substrate 101. The grooves 140 are formed into the optoelectronic component 102. The protrusions are formed at the edges of the photonic substrate 101. Further, the bonding structure 100 has a silicon (Si) waveguide 160 on the photonic substrate. So, the bonding structure 100 comprises an optical connection between the photonic substrate 101 and the optoelectronic component 102. Further, the bonding structure provides precise alignment between the optoelectronic component and the silicon waveguide.

According to some embodiments, a method for forming at least one electrical connection between a photonic substrate 101 and an optoelectronic component 102 comprises providing an electroconductive pad 110 on a surface of the photonic substrate 101. The method comprises providing a first bonding material layer 121 directly and at least partially on a surface of the electroconductive pad 110. The method comprises providing a second bonding material layer 122 on a surface of the optoelectronic component 102. The method comprises bonding the first bonding material layer 121 with the second bonding material layer 122 for forming a bond layer 120. The electroconductive pad 110 for the at least one individual electrical connection comprises at least two separated portions for receiving extra bonding material of the bond layer 120 between the portions.

The first bonding material layer 121 is provided directly on a surface of the electroconductive pad 110. Then, there is no layer, such as a sealing layer, between the first bonding material layer and the electroconductive pad. This enables precise alignment between the photonic substrate and the optoelectronic component, and precise thickness control of a structure between the photonic substrate and the optoelectronic component.

FIG. 5 illustrates a photonic substrate 101 and an optoelectronic component 102 before bonding in accordance with at least some embodiments. The photonic substrate 101 comprises a passivation layer 130 on the surface on the photonic substrate 101 and the electroconductive pad 110 on the passivation layer 130. A first bonding material layer 121 is on a surface of the electroconductive pad 110. The surface comprising the passivation layer 130, the electroconductive pad 110 and the first bonding material layer 121 is facing the optoelectronic component 102. A second bonding material layer is on a surface of the optoelectronic component. The surface comprising the second bonding material layer is facing the photonic substrate 101.

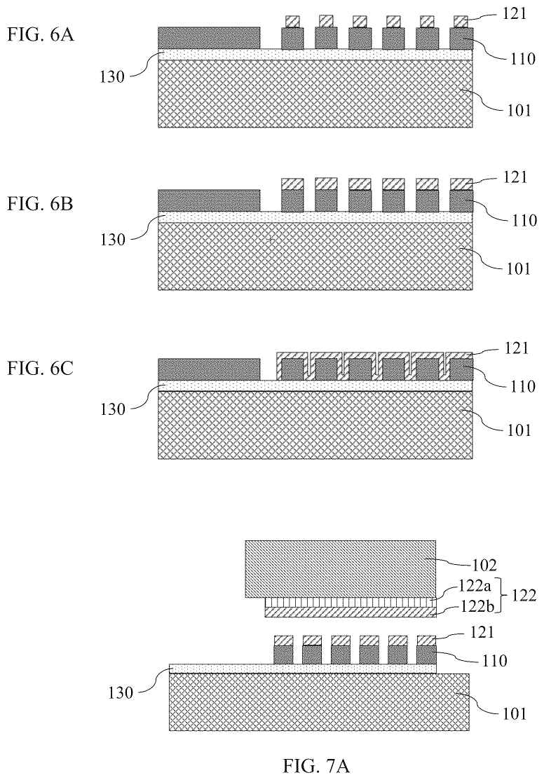

FIG. 6A illustrates a photonic substrate 101 before bonding in accordance with at least some embodiments. A first bonding material layer 121 is partially on a surface of an electroconductive pad 110. Then, the first bonding material layer 121 covers the electroconductive pad 110 only partially. So, a portion of the surface of the electroconductive pad 110 is free from the first bonding material layer 121.

FIG. 6B illustrates a photonic substrate 101 before bonding in accordance with at least some embodiments. A first bonding material layer 121 is on a surface of an electroconductive pad 110. The first bonding material layer 121 covers the whole surface of the electroconductive pad 110, which surface is facing the optoelectronic component 102, when the photonic substrate 101 and the optoelectronic component 102 is bonded.

According to some embodiments, the method comprises providing a first bonding material layer 121 on the surface of the photonic substrate 101.

FIG. 6C illustrates a photonic substrate 101 before bonding in accordance with at least some embodiments. A first bonding material layer 121 is on a surface of an electroconductive pad 110, which surface is facing the optoelectronic component 102, when the photonic substrate 101 and the optoelectronic component 102 is bonded. Further, the first bonding material layer 121 is at least partially on a surface of the photonic substrate 101. Furthermore, the first bonding material layer 121 is at least partially between portions of the electroconductive pad 110.

According to some embodiment, the method comprises providing a passivation layer 130 on the photonic substrate 101. Then, the electroconductive pad 110 can be provided on the surface of the passivation layer 130.

According to some embodiments, a bonding temperature for bonding the first bonding material layer 121 with the second bonding material layer 122 is lower than a melting temperature of the electroconductive pad 110. The bonding temperature can be for example, at least 150° C., preferably 150 to 550° C., lower than the melting temperature of the electroconductive pad 110. For example, gold-tin (AuSn) bonding can be conducted at about 220° C. or gold-indium (AuIn) can be conducted at about 150° C., while the melting temperature of the electroconductive pad 110 comprising aluminum is about 660° C. Thus, the electroconductive pad 10 is not deformed or melted during the bonding. The electroconductive pad ensures that the photonic substrate 101 and the optoelectronic component 102 are separated by the gap between the photonic substrate 101 and the optoelectronic component 102 during the bonding. In addition, a height of the gap can be adjusted by the height of the electroconductive pad. Thus, the electroconductive pad provides good gap control between the photonic substrate and the optoelectronic component.

According to some embodiments, bonding of the first bonding material layer 121 with the second bonding material layer 122 is provided by eutectic bonding, solder bonding or solid-liquid interdiffusion.

Eutectic bonding does not require use of high contact force during the bonding. Eutectic bonding is less sensitive to surface flatness irregularities, scratches, as well as to particles compared to the direct wafer bonding methods, because the eutectic bonding process goes through a liquid phase.

In eutectic bonding, temperature can be raised to a value lower than the eutectic temperature of the eutectic alloy. Then, temperature can be maintained constant for short time to reach uniform heating of both the photonic substrate and the optoelectronic component. After that, temperature can be increased to a temperature exceeding the eutectic point. Finally, the structure can cool down to a temperature below the eutectic temperature.

Eutectic bonding can be conducted 10 to 20° C. above eutectic temperature of a eutectic alloy. For example, gold-tin (AuSn) bonding can be conducted at 220° C., aluminum-germanium (AlGe) bonding can be conducted at 420° C., gold-indium (AuIn) bonding can be conducted at 150° C., and copper-tin (CuSn) bonding can be conducted at 400° C.

Bonding can be conducted in a bonding chamber. A controlled vacuum pressure can be formed in the bonding chamber. The vacuum pressure can be for example, 0.8 10⁻⁵ mbar. One or more inert gases, such as argon and nitrogen, can be introduced to the bonding chamber.

The first bonding material layer 121 and the second bonding material layer 122 can comprise same or different materials. The first bonding material layer 121 and the second bonding material layer 122 can comprise metal or metal alloy.

Both the first bonding material layer 121 and/or the second bonding material layer 122 can comprise tin (Sn), gold (Au), aluminium (Al), germanium (Ge), copper (Cu), indium (In), gold-tin (AuSn), aluminium-germanium (AlGe), copper-tin (CuSn), gold-indium (AuIn) or tantalum nitride (TaN).

For example, the first bonding material layer 121 can comprise tin (Sn) and the second bonding material layer can comprise copper (Cu), or vice versa. For example, the first bonding material layer 121 can comprise tin (Sn) and the second bonding material layer can comprise copper-tin (CuSn), or vice versa. For example, the first bonding material layer 121 can comprise Cu (copper) and the second bonding material layer can comprise copper-tin (CuSn), or vice versa. For example, the first bonding material layer 121 and the second material layer 122 can comprise copper-tin (CuSn). Corresponding metal or metal alloy combinations may also be formed by the other metals and metal alloys listed above.

The first bonding material layer 121 can comprise two layers, a first layer 121a and a second layer 121b. The first layer 121a and the second layer 121b can be at least partially on top of each other. The first layer 121a and the second layer 121b can comprise different metals. For example, the first layer 121a can comprise gold (Au), aluminium (Al) or copper (Cu), and the second layer 121b can comprise tin (Sn), germanium (Ge) or tin (Sn), respectively.

Alternatively or in addition, the second bonding material layer 122 can comprise two layers, a first layer 122a and a second layer 122b. The first layer 122a and the second layer 122b can be at least partially on top of each other. The first layer 122a and the second layer 122b can comprise different metals. For example, the first layer 122a can comprise gold (Au), aluminium (Al) or copper (Cu), and the second layer 122b can comprise tin (Sn), germanium (Ge) or tin (Sn), respectively.

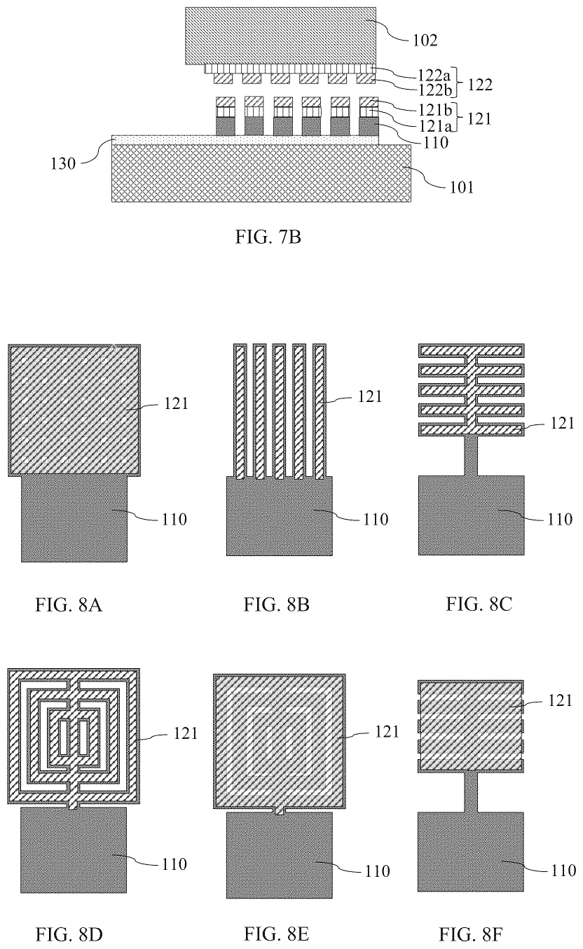

FIG. 7A illustrates a photonic substrate 101 and an optoelectronic component 102 before bonding. An electroconductive pad 110 is on a surface if the photonic substrate 101. A first bonding material layer 121 is on a surface of the electroconductive pad 110. The first bonding material layer 121 can comprise metal or metal alloy. A second bonding material layer 122 is on a surface of an optoelectronic component 102, which surface is facing the photonic substrate 101, when the photonic substrate 101 and the optoelectronic component 102 is bonded. The second bonding material layer 122 comprises two layers, a first layer 122a and a second layer 122b, on top of each other. The first layer 122a and the second layer 122b can comprise different metals. For example, the first bonding material layer 121 can comprise gold-tin (AuSn), the first layer 122a of the second bonding material layer 122 can comprise gold (Au) and the second layer 122b of the second bonding material layer 122 can comprise tin (Sn).

FIG. 7B illustrates a photonic substrate 101 and an optoelectronic component 102 before bonding. The electroconductive pad 110 is on a surface if the photonic substrate 101. A first bonding material layer 121 is on a surface of the electroconductive pad 110. The first bonding material layer 121 comprises two layers, a first layer 121a and a second layer 121b, on top of each other. The first layer 121a and the second layer 121b can comprise different metals. The second bonding material layer 122 is on a surface of the photonic substrate 102, which surface is facing the photonic substrate 101, when the photonic substrate 101 and the optoelectronic component 102 is bonded. The second bonding material layer 122 comprises two layers, a first layer 122a and a second layer 122b, on top of each other. The second layer 122b covers the first layer 122a partially. The first layer 122a and the second layer 122b can comprise different metals. For example, the first layer 121a of the first bonding material layer 121 can comprise gold (Au) and the second layer 121b of the first bonding material layer 121 can comprise tin (Sn). The first layer 122a of the second bonding material layer 122 can comprise gold (Au) and the second layer 122b of the second bonding material layer 122 can comprise tin (Sn).

The electroconductive pad 110 comprising at least two portions can comprise at least one gap between the portions. The bond layer 120 can be located in the gap. The gap between the portions of the electroconductive pad can have a predetermined width of 3 to 100 μm, such as 5 to 20 μm.

FIG. 8A illustrates an electroconductive pad 110 and a first bonding material layer 121 on a surface of the electroconductive pad 110. The electroconductive pad 110 comprises a plurality of separated holes for receiving extra bonding material. The holes form a regular pattern. The holes have square shape. However, the holes can have any other suitable shape, such as round, oval, triangular or rectangular.

FIG. 8B illustrates that an electroconductive pad 110 and a first bonding material layer 121 on a surface of the electroconductive pad 110. The electroconductive pad 110 comprises a plurality separated elongated portions. There is gaps between the portions for receiving extra bonding material.

FIG. 8C illustrates an electroconductive pad 110 and a first bonding material layer 121 on a surface of the electroconductive pad 110. The electroconductive pad 110 comprises a branched structure. There is gaps between the branches for receiving extra bonding material.

FIG. 8D illustrates an electroconductive pad 110 and a first bonding material layer 121 on a surface of the electroconductive pad 110. The electroconductive pad 110 comprises a plurality of separated holes for receiving extra bonding material.

FIG. 8E illustrates an electroconductive pad 110 and a first bonding material layer 121 on a surface of the electroconductive pad 110. The electroconductive pad 110 comprises a plurality of separated holes for receiving extra bonding material. The first bonding material layer 121 extends also on the surfaces of the holes.

FIG. 8F illustrates an electroconductive pad 110 and a first bonding material layer 121 on a surface of the electroconductive pad 110. The electroconductive pad 110 comprises a branched structure. There is gaps between the branches for receiving extra bonding material. The first bonding material layer 121 extends also on the surfaces of the gaps.

According to some embodiments, the method comprises providing at least one groove 140 in the optoelectronic component 102 and at least one protrusion 150 on the photonic substrate 101 for aligning the optoelectronic component 102 with the photonic substrate 101. This provides better alignment accuracy between the photonic substrate and the optoelectronic component. Better alignment accuracy minimizes risk for fractures of the photonic substrate and the optoelectronic component.

A layer of protrusion material can be formed over the surface of the photonic substrate using deposition techniques, such as sputtering, evaporation, chemical vapor deposition or physical vapor deposition.

The protrusion 150 can be formed from a material of the passivation layer

The protrusion 150 can be formed from the protrusion material by for example, optical photolithography.

The groove can be formed in the optoelectronic component 102 by for example, optical photolithography.

According to some embodiments, the method comprises providing the first bonding material layer 121 on the at least one protrusion 150 and/or the second bonding material layer 122 on the at least one groove 140. The bonding material layer(s) 121, 122 provides smooth movement of the protrusion into the groove during the bonding the photonic substrate and the optoelectronic component, because liquid metal reduces friction between the surfaces of the protrusion and the groove by working as a lubricant.

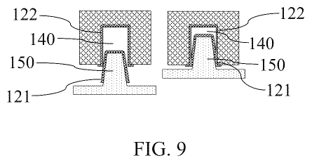

FIG. 9 illustrates a protrusion 150 and a groove 140 in accordance with at least some embodiments of the present invention. The protrusion 150 has a shape of a pillar, which pillar is tapering towards the optoelectronic component 102. A first bonding material layer 121 is on the surface of the protrusion 150. The second bonding material layer 122 is on the groove.

The bonding structure 100 can be used in a telecommunication, a datacommunication, an environmental sensing, an industrial sensing, a medial or a light detection and ranging (LIDAR) application.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, i.e. a singular form, throughout this document does not exclude a plurality.

### REFERENCE SIGNS LIST

100 bonding structure
101 photonic substrate
102 optoelectronic component
110 electroconductive pad
120 bond layer
121 first bonding material layer
121a first layer of first bonding material layer
121b second layer of first bonding material layer
122 second bonding material layer
122a first layer of second bonding material layer
122b second layer of second bonding material layer
130 passivation layer
140 groove
150 protrusion
160 waveguide

1. A bonding structure for forming at least one electrical connection between a photonic substrate and an optoelectronic component, the bonding structure comprising:
an electroconductive pad between the photonic substrate and the optoelectronic component, wherein the electroconductive pad comprises at least two separated portions, and
a bond layer between the electroconductive pad and the optoelectronic component, and between the at least two portions of the electroconductive pad.

2. The bonding structure of claim 1, wherein the bond layer comprises a eutectic alloy, a solder alloy or an intermetallic alloy.

3. The bonding structure of claim 1, wherein the electroconductive pad has a predetermined height of 0.2 to 1 μm.

4. The bonding structure of claim 1, further comprising an optical connection between the photonic substrate and the optoelectronic component.

5. The bonding structure of claim 1, further comprising a passivation layer on the photonic substrate.

6. The bonding structure of claim 1, wherein the optoelectronic component comprises at least one groove and the photonic substrate comprises at least one protrusion configured to the at least one groove for aligning the optoelectronic component with the photonic substrate.

7. The bonding structure of claim 6, wherein the bond layer extends on the at least one protrusion and/or on the at least one groove.

8. The bonding structure of claim 6, wherein the at least one protrusion has a shape of a pillar, which pillar tapers towards the optoelectronic component, and wherein the at least one groove has substantially the same shape as the at least one protrusion and widens towards the photonic substrate.

9. The bonding structure of claim 1, wherein the photonic substrate is silicon photonic chip or wafer.

10. The bonding structure of claim 1, wherein the optoelectronic component is a semiconductor optical amplifier, a photodiode or a laser diode.

11. A method for forming at least one electrical connection between a photonic substrate and an optoelectronic component comprising:
providing an electroconductive pad on a surface of the photonic substrate,
providing a first bonding material layer directly and at least partially on a surface of the electroconductive pad,
providing a second bonding material layer on a surface of the optoelectronic component, and
bonding the first bonding material layer with the second bonding material layer for forming a bond layer,
wherein the electroconductive pad for the at least one individual electrical connection comprises at least two separated portions for receiving extra bonding material of the bond layer between the portions.

12. The method of claim 11, further providing the first bonding material layer on the surface of the photonic substrate.

13. The method of claim 11, further comprising providing a passivation layer on the photonic substrate.

14. The method of claim 11, wherein a bonding temperature for bonding the first bonding material layer with the second bonding material layer is lower than a melting temperature of the electroconductive pad.

15. The method of claim 11, wherein bonding of the first bonding material layer with the second bonding material layer is provided by eutectic bonding, solder bonding or solid-liquid interdiffusion.

16. The method of claim 11, further comprising:
providing at least one groove in the optoelectronic component, and
providing at least one protrusion on the photonic substrate for aligning the optoelectronic component with the photonic substrate.

17. The method of claim 16, further comprising providing the first bonding material layer on the at least one protrusion and/or the second bonding material layer on the at least one groove.

18. The method of claim 11, wherein the photonic substrate is silicon photonic chip or wafer.

19. The method of claim 11, wherein the optoelectronic component is a semiconductor optical amplifier, a photodiode or a laser diode.

20. (canceled)

21. The bonding structure of claim 1, wherein the electroconductive pad further comprises at least one gap between the at least two separated portions, and wherein the bond layer is further disposed in the at least one gap.
